(19) United States
(12) Patent Application Publication
(10) Pub. No.: US 2026/0223489 A1
(43) Pub. Date: Jul. 30, 2026

(54) MICRO LED UNIT, DISPLAY PANEL, AND MANUFACTURING METHOD OF MICRO LED UNIT

(71) Applicant: Hue, Inc., SHANGHAI (CN)

(72) Inventors: Anle FANG, Shanghai (CN); Weisin TAN, Shanghai (CN)

(21) Appl. No.: 19/458,637

(22) Filed: Jan. 23, 2026

(30) Foreign Application Priority Data
Jan. 26, 2025 (CN) 202510125730.2

(51) Int. Cl. H10H 20/816; H10H 20/01; H10H 20/833; H10H 29/01; H10H 29/14; H10H 29/80

(52) U.S. Cl. CPC H10H 20/816; H10H 20/014; H10H 20/833; H10H 29/011; H10H 29/14; H10H 29/8323

(57) ABSTRACT

A Micro-Light Emitting Diode (Micro LED) unit, a Micro LED display panel, and a method for manufacturing the Micro LED unit are provided. The Micro LED unit includes: a transparent conductive layer, a first contact layer, a first cladding layer, a light emitting layer, a second cladding layer, and a second contact layer, which are stacked from top to bottom. The first contact layer includes a metal doped region doped with a metal material. In some embodiments of the present disclosure, the Micro LED unit includes the metal doped region doped with the metal material, thereby improving conductivity of the Micro LED unit and consequently improving luminous efficiency of the Micro LED unit.

### CROSS-REFERENCE TO RELATED APPLICATIONS

The present disclosure claims the benefits of priority to Chinese Application No. 202510125730.2, filed on January 26, 2025, which is incorporated herein by reference in its entirety.

### TECHNICAL FIELD

The present disclosure relates to a Micro Light Emitting Diode (Micro LED) field, and more particularly to a Micro LED unit, a Micro LED display panel, and a method for manufacturing the Micro LED unit.

### BACKGROUND

Micro LED is also known as a miniature light emitting diode. A Micro LED display panel includes a high-density integrated LED array, with a distance between LED pixels in the array on the order of micrometers (μm), and each LED pixel is self-emissive. Micro LEDs have been widely used in various display fields. For example, Micro LEDs can serve as pixel units in display fields such as Virtual Reality (VR), Augmented Reality (AR) or Mixed Reality (MR).

In conventional technologies, a Micro LED may be coupled to a drive circuit via an electrode, and the drive circuit can control an on/off state and brightness of an individual Micro LED. In some technologies, the electrode of the Micro LED (e.g., a top electrode in a light emitting direction of the Micro LED) may be formed using a metal material. For example, a metal electrode may be disposed at a top center of a Micro LED body, thereby achieving electrical coupling between layers below the Micro LED body and a transparent conductive layer above the Micro LED body. The metal electrode may cause a portion of emitted light from the Micro LED to be blocked or absorbed, thereby reducing luminous efficiency of the Micro LED. In some technologies, a size of the top electrode may be reduced through metal agglomeration. For example, the top N-type electrode of some red Micro LEDs may be formed from a metal material (including elemental metals, alloys, etc.) under a high-temperature annealing condition. After high-temperature annealing, the metal agglomeration may reduce an area of the N-type electrode, but still has strong obstruction and absorption on axial light, which may cause a decrease in a light-receiving ratio within a certain angle range around a light emitting central axis (also known as a normal direction) of the Micro LED. As the luminous efficiency of the Micro LED decreases, it may be necessary to increase a drive voltage of Micro LED to achieve desired brightness, which may increase energy consumption of a Micro LED display panel.

Therefore, it is necessary to propose an improved Micro LED unit that further reduces obstruction of light by the electrode while maintaining ohmic contact of a top contact layer, thereby further improving efficiency of the Micro LED unit.

### SUMMARY

To address the aforementioned technical problems, embodiments of the present disclosure provide a Micro LED unit, a Micro LED display panel, and a method for manufacturing the Micro LED unit. A top contact layer is doped with a metal material to form a metal doped region to reduce obstruction of light by an electrode while maintaining ohmic contact of the top contact layer, thereby further improving efficiency of the Micro LED unit.

Some embodiments of the present disclosure provide a Micro LED unit which includes: a transparent conductive layer, a first contact layer, a first cladding layer, a light emitting layer, a second cladding layer, and a second contact layer, which are stacked from top to bottom, where the first contact layer includes a metal doped region doped with a metal material.

Some embodiments of the present disclosure provide a Micro LED display panel, which includes: a drive circuit; and Micro LED units as described above, the Micro LED units being arranged on the drive circuit and driven by the drive circuit.

Some embodiments of the present disclosure provide a method for manufacturing a Micro LED display unit, which includes: forming a second contact layer, a second cladding layer, a light emitting layer, a first cladding layer, a first contact layer, and a transparent conductive layer sequentially on a substrate; and doping the first contact layer with a metal material to form a metal doped region.

With the Micro LED unit, the Micro LED display panel, and the method for manufacturing the Micro LED unit according to some embodiments of the present disclosure, a top contact layer is doped with a metal material to form a metal doped region to reduce obstruction of light by an electrode while maintaining ohmic contact of the top contact layer, thereby further improving efficiency of the Micro LED unit. It should be noted that the embodiments of the present disclosure do not necessarily require complete realization of the above-mentioned technical effect, and the technical effect achieved by solving at least one technical problem constitutes a contribution to prior art.

### BRIEF DESCRIPTION OF THE DRAWINGS

The above and other objects, features and advantages of the present disclosure will become more apparent from more detailed description of exemplary embodiments of the present disclosure taken in conjunction with accompanying drawings, where same reference numerals generally denote same parts.

FIG. 1 illustrates an exemplary Micro LED unit, according to some embodiments of the present disclosure.

FIG. 2 illustrates another exemplary Micro LED unit, according to some embodiments of the present disclosure.

FIG. 3 is a partial schematic diagram of an exemplary Micro LED unit, according to some embodiments of the present disclosure.

FIG. 4 illustrates another exemplary Micro LED unit, according to some embodiments of the present disclosure.

FIG. 5 illustrates an exemplary Micro LED display panel, according to some embodiments of the present disclosure.

FIG. 6 illustrates an exemplary Micro LED display device, according to some embodiments of the present disclosure.

FIG. 7 illustrates another exemplary Micro LED display device, according to some embodiments of the present disclosure.

FIG. 8 illustrates an exemplary method for manufacturing a Micro LED unit, according to some embodiments of the present disclosure.

### DETAILED DESCRIPTION

Preferred embodiments of the present disclosure are described in more detail with reference to the accompanying drawings below. While preferred embodiments of the present disclosure are shown in the drawings, it should be understood that the present disclosure may be implemented in various forms and should not be limited to the embodiments set forth herein. Rather, these embodiments are provided so that the present disclosure will be thorough and complete, and will fully convey the scope of the present disclosure to those skilled in the art.

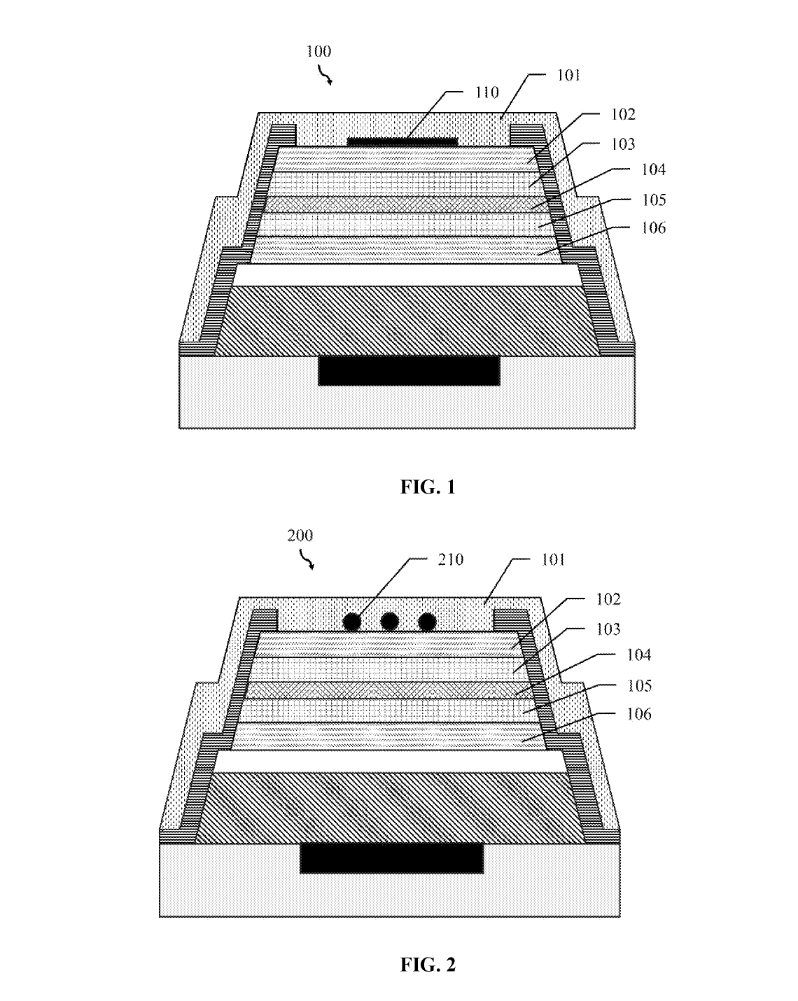

FIG. 1 illustrates a Micro LED unit 100 according to some embodiments of the present disclosure. As shown in FIG. 1, the Micro LED unit 100 includes a top transparent conductive layer 101, a first contact layer 102, a first cladding layer 103, a light emitting layer 104, a second cladding layer 105, and a second contact layer 106. The first contact layer 102 and the first cladding layer 103 may be the same type of semiconductors, for example, both being N-type semiconductors. The second cladding layer 105 and the second contact layer 106 may be the same type of semiconductors, for example, both being P-type semiconductors. In some embodiments, the first contact layer 102 and the first cladding layer 103 have a conductivity type opposite to that of the second cladding layer 105 and the second contact layer 106. For example, if the first contact layer 102 and the first cladding layer 103 are N-type semiconductors, the second cladding layer 105 and the second contact layer 106 are P-type semiconductors, and vice versa. In addition, to improve ohmic contact performance of the first contact layer 102, a metal electrode 110 may be arranged on the first contact layer 102 to improve conductivity. It could be understood that due to the block-shaped metal electrode 110, light emitted from the light emitting layer 104 may be blocked and absorbed to a certain extent, thereby affecting luminous efficiency of the Micro LED unit 100.

In some improved designs, the luminous efficiency of the Micro LED unit may be improved by adjusting the shape of the electrode. FIG. 2 illustrates a Micro LED unit 200, according to some embodiments of the present disclosure. As shown in FIG. 2, similar to the Micro LED unit 100 in FIG. 1, the Micro LED unit 200 includes a top transparent conductive layer 101, a first contact layer 102, a first cladding layer 103, a light emitting layer 104, a second cladding layer 105, and a second contact layer 106. The first contact layer 102 and the first cladding layer 103 may be the same type of semiconductors, for example, both being N-type semiconductors. The second cladding layer 105 and the second contact layer 106 may be the same type of semiconductors, for example, both being P-type semiconductors. In some embodiments, the first contact layer 102 and the first cladding layer 103 have a conductivity type opposite to that of the second cladding layer 105 and the second contact layer 106. For example, if the first contact layer 102 and the first cladding layer 103 are N-type semiconductors, the second cladding layer 105 and the second contact layer 106 are P-type semiconductors, and vice versa. In addition, to overcome light obstruction and absorption caused by the block-shaped electrode in the solution shown in FIG. 1, the Micro LED unit 200 further includes a cluster of metal electrodes 210 on the first contact layer 102 to improve conductivity. In some embodiments, the metal electrodes 210 may be formed by annealing a thin-film metal electrode material at a high temperature, and the number and size of the metal electrodes 210 are adjusted based on the size of the electrode material and annealing conditions. It could be understood that compared to the metal electrode 110 in the Micro LED unit 100, the metal electrodes 210 have a smaller area, thereby reducing the obstruction and absorption of light emitted from the light emitting layer 104.

Although the cluster of metal electrodes 210 can improve the luminous efficiency of the Micro LED unit 200 to some extent, the cluster shape of the metal electrodes 210 may still cause the light emitted by the light emitting layer 104 to be blocked. For example, it may cause a decrease in a light-receiving ratio within ±20° in a normal direction.

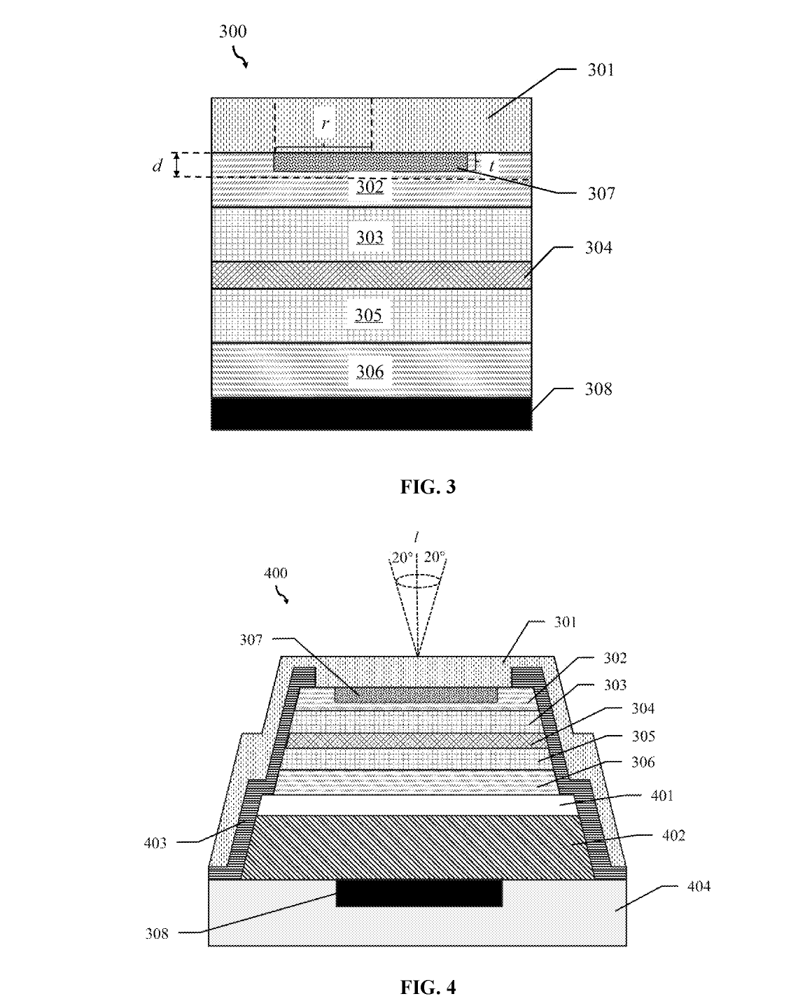

Some embodiments of the present disclosure provide a Micro LED unit. FIG. 3 illustrates a Micro LED unit 300, according to some embodiments of the present disclosure. It could be understood that various components shown are illustrated to demonstrate main working principles of the Micro LED unit 300, the size and shape of the various components in the actual Micro LED unit may differ from those shown, and relative positional relationships between these components may also differ from those shown. In addition, for the purpose of clearly showing a main structure of the Micro LED unit 300, some other components in the Micro LED unit 300 are omitted. In some embodiments, the Micro LED unit 300 may be a red Micro LED unit. Basic principles of the present disclosure are explained below using the red Micro LED unit as an example. It could be understood that the basic principles of the present disclosure can also be applied to Micro LED units of other colors.

As shown in FIG. 3, the Micro LED unit 300 includes a transparent conductive layer 301, a first contact layer 302, a first cladding layer 303, a light emitting layer 304, a second cladding layer, and a second contact layer 306, which are stacked from top to bottom. In some embodiments, the transparent conductive layer 301 on top of the Micro LED unit 300 may be made of a transparent conductive material such as Transparent Conductive Oxide (TCO), Indium Tin Oxide (ITO), Antimony doped Zinc Oxide (AZO), Antimony doped Tin Oxide (ATO), Fluorine doped Tin Oxide (FTO), or Antimony doped Zinc Oxide (AZO). The first contact layer 302 and the first cladding layer 303 are the same type of semiconductors, while the second cladding layer 305 and the second contact layer 306 are the same type of semiconductors. For example, in some embodiments, the first contact layer 302 and the first cladding layer 303 may both be N-type semiconductor layers, and the second contact layer 306 and the second cladding layer 305 may both be P-type semiconductor layers. For example, the first contact layer 302 may be formed by doping Si with one of following materials: GaAs, AlInP, AlₓGa₍₁₋ₓ₎ InP (0.01 ≤ x ≤ 0.99), where a doping concentration of Si is within a range of 1e¹⁶ to 1e²⁰.In other examples, the first contact layer 302 and the first cladding layer 303 may both be P-type semiconductor layers, and the second contact layer 306 and the second cladding layer 305 may both be N-type semiconductor layers. The basic principles of the present disclosure are explained below with the first contact layer 302 and the first cladding layer 303 being N-type semiconductor layers and the second contact layer 306 and the second cladding layer 305 being P-type semiconductor layers.

Still referring to FIG. 3, the first contact layer 302 also includes a metal doped region 307 doped with a metal material. In the context of the present disclosure, "metal material" refers to a material that retains electrical properties of a metal, such as a pure metal or an alloy. Instead of using the block-shaped and cluster-shaped electrodes mentioned above, the Micro LED unit 300 enhances the conductivity between the transparent conductive layer 301 and the first contact layer 302 by using the metal doped region. Specifically, the metal doped region 307 participates in forming an ohmic contact between the transparent conductive layer 301 and the first contact layer 302. It could be understood that compared to not configuring a metal doped region 307, the metal doped region 307 may improve contact resistivity of the ohmic contact.

In some embodiments, the metal doped region 307 is formed from one or more of following metal materials: Au, Ge, Pd, Ni, Ti, Pt, etc. In some embodiments, the material of the metal doped region 307 includes: AuGe, PdGe, PdSi, NiGeAu, NiGe, NiAu, Ti, Pt, or Au. For example, the metal doped region 307 is formed as an AuGe alloy region, or as a combined Au and Ge thin film layer. To form a good ohmic contact, if two metal materials Au and Ge are formed into an AuGe alloy region, the alloy formed by Au and Ge may satisfy a stoichiometric ratio AuₓGe₍₁₋ₓ₎ (0 < x < 1).

In some embodiments, thickness t of the metal doped region 307 satisfies a relationship: t ≤ 1μm. In the context of the present disclosure, the thickness t of the metal doped region 307 represents height to which the metal doped region 307 can be doped within the first contact layer 302. Limiting the thickness t of the metal doped region 307 to be relatively small may prevent thickness accumulation from causing obstruction or absorption of light emitted from the light emitting layer 304. On the other hand, thinner metal doping also reduces requirements for a doping process and lowers difficulty of doping. In some embodiments, the metal doped region 307 is formed between the upper surface of the first contact layer 302 and a predetermined depth d below the upper surface. In other words, the doping depth d of the metal doped region 307 refers to the depth of doping of the metal doped region 307 at and below the upper surface of the first contact layer 302, with the upper surface of the first contact layer 302 as a reference standard. For example, the predetermined depth d may satisfy a relationship: 0.1μm ≤ d ≤ 1μm. In some embodiments, within the ranges of thickness t and preset depth d, the metal doped region 307 may be well integrated into the first contact layer 302 to form good bonding, thereby ensuring an effective charge transport channel. When the thickness t is greater than 1μm or the preset depth d is greater than 1μm, structural stability of the first contact layer 302 may be excessively affected. On the other hand, from a process perspective, the preset depth d of 0.1μm to 1μm facilitates precise control of the doping process. In modern semiconductor manufacturing processes, the precise control of depth is one of essential factors to achieve high-performance devices. The range of depth may be easily achieved using existing technologies and can ensure high process repeatability and stability. Further, metal doping within the range of depth also helps to reduce process errors and uncertainties, thereby improving production yield.

In some embodiments, the metal material in the metal doped region 307 has a dispersion radius of r on the upper surface of the first contact layer 302, satisfying a relationship: 0.1μm ≤ r ≤ 10μm. Controlling a doping range of the metal material within the range of dispersion radius r ensures that the metal material distribution is neither too concentrated, leading to excessively high local current density and causing overheating and potential damage, nor too dispersed, rendering improvement on performance of the contact layer insignificant. For example, when the radius r is less than 0.1μm, the metal doping amount may be insufficient, making it difficult to effectively improve contact resistance and conductivity. When the radius r is greater than 10μm, it may lead to uneven current distribution, affecting overall stability and reliability of the device. Besides, the range of dispersion radius allows for better coordination with subsequent process steps. For the doping process, the range of dispersion radius from 0.1μm to 10μm may reduce process difficulty and cost while ensuring accuracy. A radius r that is too small may require higher precision equipment and more complex process control, increasing production cost. A radius r that is too large may cause uncertainty in the doping range. Based on specific design requirements and performance indicators, selecting an appropriate metal dispersion radius within the range of 0.1μm ≤ r ≤ 10μm can achieve better performance, which is of positive significance for improving performance of electronic devices and reducing production cost.

FIG. 4 illustrates a Micro LED unit 400 according to some embodiments of the present disclosure. The Micro LED unit 400 is constructed in a shape that is narrower at the top and wider at the bottom, as shown in FIG. 4, and includes a structure of layers as shown in FIG. 3. Specifically, the Micro LED unit 400 includes a transparent conductive layer 301, a first contact layer 302, a first cladding layer 303, a light emitting layer 304, a second cladding layer 305, and a second contact layer 306, which are stacked from top to bottom.

Still referring to FIG. 4, the Micro LED unit 400 further includes a metal doped region 307 formed by doping a metal material in the first contact layer 302. In some embodiments, by controlling doping properties of the metal material (e.g., material, thickness, depth, or dispersion radius as described above), light transmittance of the metal doped region 307 along an axial direction of a central axis l of the Micro LED unit 400 is above a preset threshold (e.g., 95%). In some embodiments, the light transmittance of the metal doped region 307 within a 20° reception angle range relative to the central axis l of the Micro LED unit 400 is above a preset threshold (e.g., 93%).

As shown in FIGS. 3 and 4, in some embodiments, the Micro LED unit 400 further includes an electrode 308 disposed below the second contact layer 306. For example, the electrode 308 may be formed from at least one of following materials: AuZn alloy, AuBe alloy, or Indium Tin Oxide (ITO). AuZn alloy and AuBe alloy may be used to form non-transparent electrodes, while ITO may be used to form transparent electrodes. In some embodiments, the Micro LED unit 400 is an AlGaInP-based Micro LED unit.

Further, as shown in FIG. 4, the Micro LED unit 400 may also include a transparent conductive layer 401 and a metal bonding layer 402 on the electrode 308 and under the second contact layer 306. The transparent conductive layer 401 and the metal bonding layer 402 may form an Omni-Directional Reflector (ODR) structure with high reflection efficiency. In some embodiments, the transparent conductive layer 401 may be made of a transparent conductive material, such as Transparent Conductive Oxide (TCO), Indium Tin Oxide (ITO), Antimony doped Zinc Oxide (AZO), Antimony doped Tin Oxide (ATO), Fluorine doped Tin Oxide (FTO), or Antimony doped Zinc Oxide (AZO). A material of the metal bonding layer 402 may be one or more of various metals, including Al, Au, Rh, Ag, Cr, Ti, Pt, Sn, Cu, AuSn, or TiW. The transparent conductive layer 401 can form an ohmic contact layer between the metal bonding layer 402 and the second contact layer 306.

Still referring to FIG. 4, the Micro LED unit 400 may further include a passivation layer 403 disposed on the transparent conductive layer 301 and sides of each layer of the Micro LED unit 400 body (including the first contact layer 302, the first cladding layer 303, the light emitting layer 304, the second cladding layer 305, the second contact layer 306, the transparent conductive layer 401, and the metal bonding layer 402). The passivation layer 403 is disposed on the sides of each layer of the body, thereby preventing the transparent conductive layer 301 from directly contacting with the sides of each layer of the light emitting body to form electrical connection. In some embodiments, the passivation layer 403 may be a transparent layer. For example, a material of the passivation layer 403 may include a combination of one or more selected from SiO₂, SiON, Al₂O₃, and SiN.

Still referring to FIG. 4, the Micro LED unit 400 may further include a substrate 404 (also called an integrated circuit backplane), and the layers described above (e.g., the transparent conductive layer 301, the first contact layer 302, the first cladding layer 303, the light emitting layer 304, the second cladding layer 305, the second contact layer 306, the transparent conductive layer 401, the metal bonding layer 402, the electrode 308, and the passivation layer 403) may be formed on the substrate 404.

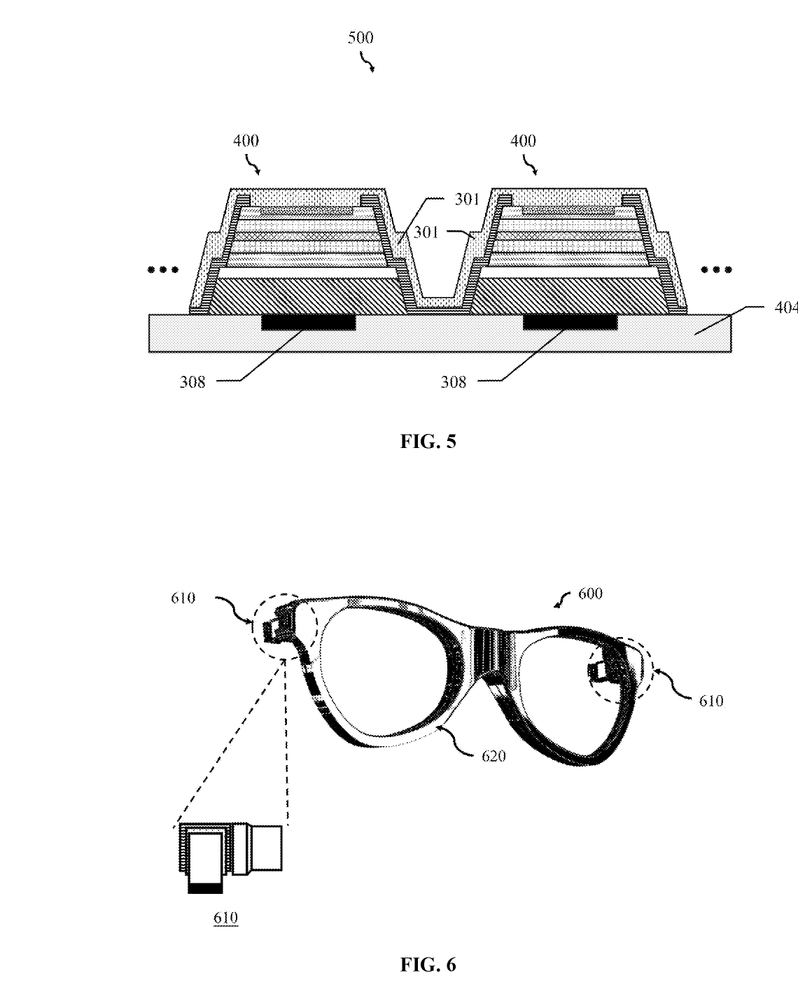

Some embodiments of the present disclosure provide a Micro LED display panel. FIG. 5 illustrates a Micro LED display panel 500 according to some embodiments of the present disclosure. As shown in FIG. 5, the Micro LED display panel 500 includes a substrate 404 (an integrated circuit backplane). A plurality of electrodes 308 are embedded in the substrate 404 (the integrated circuit backplane), and one electrode 308 corresponds to one Micro LED unit 400. Each Micro LED unit 400 is disposed on a top surface of the substrate 404 (the integrated circuit backplane). In the present disclosure, the top surface of the substrate 404 (the integrated circuit backplane) is a surface of the substrate 404 (the integrated circuit backplane) that can be used for arranging various components. It could be understood that the top surface of the substrate 404 (the integrated circuit backplane) or a bottom surface of the substrate 404 that is opposite to the top surface is generally larger than other sides of the substrate 404 (integrated circuit backplane). As shown in FIG. 5, two Micro LED units 400 are shown in the Figure for illustrative purpose. It could be understood that the Micro LED display panel 500 may include more Micro LED units 400 extending laterally and longitudinally in a plane. In some embodiments, as shown in FIG. 5, the transparent conductive layers 301 of the Micro LED units 400 are interconnected, forming a continuous transparent conductive layer. The continuous transparent conductive layer may be connected to another electrode (e.g., a common electrode) on the substrate 404 (the integrated circuit backplane), allowing each Micro LED unit 400 to be driven by the substrate 404 (the integrated circuit backplane). A structure (not shown) to prevent light crosstalk may also be provided between adjacent Micro LED units 400 to prevent light from adjacent Micro LED units 400 from interfering with each other and affecting imaging effect.

FIG. 6 illustrates a Micro LED display device according to some embodiments of the present disclosure. As shown in FIG. 6, a Near-Eye Display (NED) 600 (e.g., VR glasses) includes a pair of multi-color projectors 610 and a frame 620 for fixing the multi-color projectors 610. The NED 600 may also include other components, which are omitted here for explicitly describing configuration of the NED 600. Each multi-color projector 610 may be disposed at an end of a temple (not shown) of the NED 600. A power supply system and processing system for driving the multi-color projectors 610 may be embedded in the temple. An image presented by each multi-color projector 610 can be captured by eyes of a viewer (not shown), thereby rendering a virtual scene or enhancing a scene for the viewer. In some embodiments, the term "render" may also be used as a synonym such as "display" or "show". It could be understood that each multi-color projector 610 may include three Micro LED panels of different colors (e.g., corresponding to the Micro LED display panel 500 in FIG. 5) and a combiner (e.g., a combining prism). The combiner is used to combine (also known as “composite”) images rendered by three Micro LED panels into a composite image.

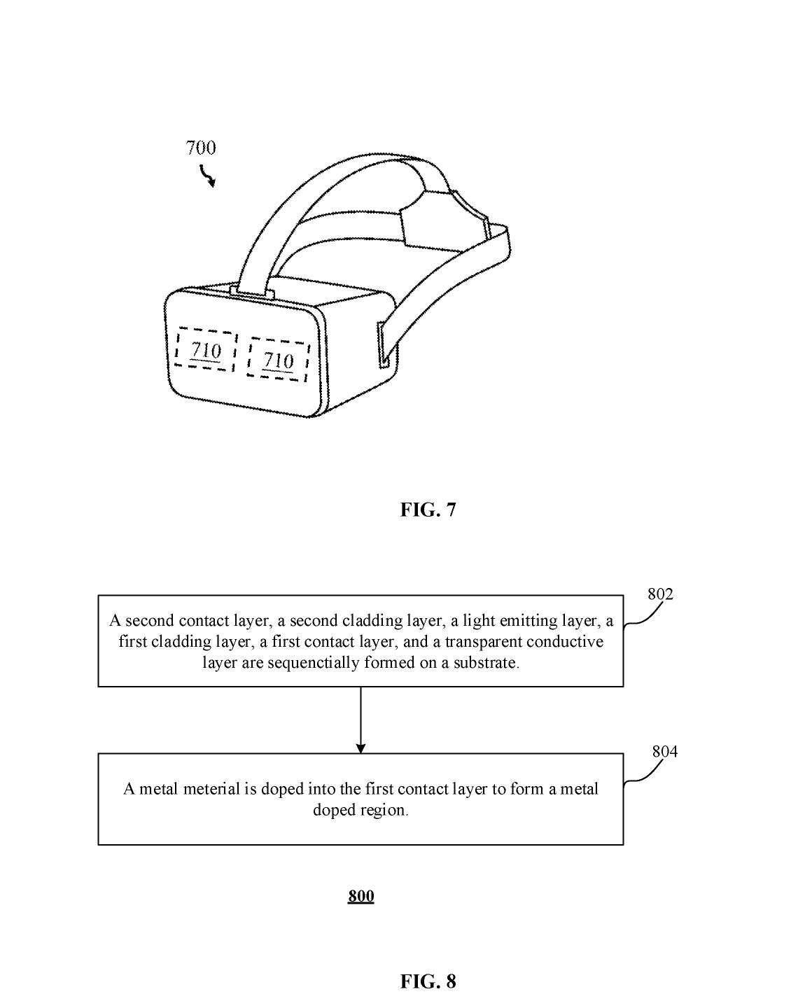

FIG. 7 illustrates a Micro LED display device according to some embodiments of the present disclosure. As shown in FIG. 7, a head-mounted virtual reality device 700 includes two Micro LED panels 710 (e.g., corresponding to the Micro LED display panel 500 in FIG. 5). Although not shown, the head-mounted virtual reality device 700 may also include a Central Processing Unit (CPU), a Graphic Processing Unit (GPU) as a signal source, and other related circuits. Introducing the Micro LED panels into the head-mounted virtual reality device 700 can improve luminous efficiency, thereby reducing energy consumption and improving image quality.

Some embodiments of the present disclosure provide a method for manufacturing a Micro LED unit. FIG. 8 illustrates a method 800 for manufacturing a Micro LED display unit according to some embodiments of the present disclosure. Referring to FIG. 4 and FIG. 8, the method 800 includes following steps 802 and 804.

In 802, a metal bonding layer (e.g., the metal bonding layer 402), a transparent conductive layer (e.g., the transparent conductive layer 401), one contact layer (e.g., the second contact layer 306), one cladding layer (e.g., the second cladding layer 305), a light emitting layer (e.g., the light emitting layer 304), another cladding layer (e.g., the first cladding layer 303), another contact layer (e.g., the first contact layer 302), and a transparent conductive layer (e.g., the transparent conductive layer 301) are sequentially formed on a substrate (e.g., the substrate 404). The Micro LED unit formed in 802 may include the features described above regarding the Micro LED unit 400, and the relevant content is incorporated herein by reference and is not repeated here.

In 804, a metal material is doped into the first contact layer (e.g., the first contact layer 302) to form a metal doped region (e.g., metal doped region 307). The metal doped region formed in 804 may include features described above for the metal doped region, and the relevant content is incorporated herein by reference and is not repeated here.

It should be noted that relational terms herein such as “first” and “second” are used only to differentiate an entity or operation from another entity or operation, and do not require or imply any actual relationship or sequence between these entities or operations. Moreover, the words “comprising,” “having,” “containing,” and “including,” and other similar forms are intended to be equivalent in meaning and be open ended in that an item or items following any one of these words is not meant to be an exhaustive listing of such item or items, or meant to be limited to only the listed item or items.

As used herein, unless specifically stated otherwise, the term “or” encompasses all possible combinations, except where infeasible. For example, if it is stated that a database may include A or B, then, unless specifically stated otherwise or infeasible, the database may include A, or B, or A and B. As a second example, if it is stated that a database may include A, B, or C, then, unless specifically stated otherwise or infeasible, the database may include A, or B, or C, or A and B, or A and C, or B and C, or A and B and C.

In the foregoing specification, embodiments have been described with reference to numerous specific details that can vary from implementation to implementation. Certain adaptations and modifications of the described embodiments can be made. Other embodiments can be apparent to those skilled in the art from consideration of the specification and practice of the present disclosure disclosed herein. It is intended that the specification and examples be considered as exemplary only, with a true scope and spirit of the present disclosure being indicated by the following claims. It is also intended that the sequence of steps shown in figures are only for illustrative purposes and are not intended to be limited to any particular sequence of steps. As such, those skilled in the art can appreciate that these steps can be performed in a different order while implementing the same method.

In the drawings and specification, there have been disclosed exemplary embodiments. However, many variations and modifications can be made to these embodiments. Accordingly, although specific terms are employed, they are used in a generic and descriptive sense only and not for purposes of limitation.

What is claimed is:

1. A Micro-Light Emitting Diode (Micro LED) unit, comprising:
a transparent conductive layer, a first contact layer, a first cladding layer, a light emitting layer, a second cladding layer, and a second contact layer, which are stacked from top to bottom, wherein the first contact layer comprises a metal doped region doped with a metal material.

2. The Micro LED unit according to claim 1, wherein the metal doped region participates in forming an ohmic contact between the transparent conductive layer and the first contact layer.

3. The Micro LED unit according to claim 2, wherein the metal doped region is configured to improve contact resistivity of the ohmic contact.

4. The Micro LED unit according to claim 2, wherein the metal doped region comprises one or more of following metal materials: Au, Ge, Pd, Ni, Ti, or Pt.

5. The Micro LED unit according to claim 4, wherein the metal doped region is formed as an AuGe alloy region or as a combined Au and Ge thin film layer.

6. The Micro LED unit according to claim 1, wherein a thickness of the metal doped region is 1μm or less.

7. The Micro LED unit according to claim 6, wherein the metal doped region is formed between an upper surface of the first contact layer and a predetermined depthbelow the upper surface.

8. The Micro LED unit according to claim 7, wherein the predetermined depth is greater than or equal to 0.1μm and less than or equal to 1μm.

9. The Micro LED unit according to claim 7, wherein a dispersion radius of the metal material in the metal doped region on the upper surface of the first contact layer is greater than or equal to 0.1μm and less than or equal to 10μm.

10. The Micro LED unit according to claim 1, wherein light transmittance of the metal doped region along an axial direction of a central axis of the Micro LED unit is above a threshold value.

11. The Micro LED unit according to claim 10, wherein the threshold value is 95%.

12. The Micro LED unit according to claim 1, wherein light transmittance of the metal doped region within a 20° reception angle range relative to a central axis of the Micro LED unit is above a threshold value.

13. The Micro LED unit according to claim 12, wherein the threshold value is 93%.

14. The Micro LED unit according to claim 1, wherein the Micro LED unit is a red Micro LED unit.

15. The Micro LED unit according to claim 1, wherein the first contact layer and the first cladding layer are both semiconductor layers of a first conductivity type, and the second contact layer and the second cladding layer are both semiconductor layers of a second conductivity type, wherein the second conductivity type is different from the first conductivity type.

16. The Micro LED unit according to claim 15, wherein the first contact layer is formed by doping Si with one of following materials: GaAs, AlInP, or AlₓGa₍₁₋ₓ₎InP(0.01 ≤ x ≤ 0.99), and a doping concentration of Si is within a range from 1e¹⁶ to 1e²⁰.

17. The Micro LED unit according to claim 1, wherein the Micro LED unit comprises an electrode disposed below the second contact layer.

18. The Micro LED unit according to claim 17, wherein the electrode comprises at least one of following materials: AuZn alloy, AuBe alloy, or indium tin oxide.

19. The Micro LED unit according to claim 1, wherein the transparent conductive layer comprises at least one of following materials: transparent conductive oxide, indium tin oxide, antimony doped zinc oxide, antimony doped tin oxide, fluorine doped tin oxide, or aluminum doped zinc oxide.

20. A Micro-Light Emitting Diode (Micro LED) display panel, comprising:
a drive circuit; and
one or more Micro LED unit arranged on the drive circuit and driven by the drive circuit;
wherein the Micro LED unit comprises:
a transparent conductive layer, a first contact layer, a first cladding layer, a light emitting layer, a second cladding layer, and a second contact layer, which are stacked from top to bottom, wherein the first contact layer comprises a metal doped region doped with a metal material.

21. A method for manufacturing a Micro-Light Emitting Diode (Micro LED) unit, comprising:
forming a second contact layer, a second cladding layer, a light emitting layer, a first cladding layer, a first contact layer, and a transparent conductive layer sequentially on a substrate; and
doping the first contact layer with a metal material to form a metal doped region.

22. The method according to claim 21, wherein the metal doped region participates in forming an ohmic contact between the transparent conductive layer and the first contact layer.

23. The method of claim 22, wherein the metal doped region is configured to improve contact resistivity of the ohmic contact.

24. The method according to claim 22, wherein the metal doped region comprises one or more of following metallic materials: Au, Ge, Pd, Ni, Ti or Pt.

25. The method according to claim 24, wherein said doping the first contact layer with the metal material to form the metal doped region comprises: doping the first contact layer with the metal material to form an AuGe alloy region, or to form a combined Au and Ge thin film layer.
